(19) United States
(12) Patent Application Publication
(10) Pub. No.: US 2024/0332451 A1
(43) Pub. Date: Oct. 3, 2024

(54) Light Emitting Element Display Device

(71) Applicant: LG Display Co., Ltd., Seoul (KR)

(72) Inventor: Taeyoung Heo, Paju-si (KR)

(21) Appl. No.: 18/415,383

(22) Filed: Jan. 17, 2024

(30) Foreign Application Priority Data
Mar. 31, 2023 (KR) 10-2023-0042723

(51) Int. Cl. H01L 33/10; H01L 25/075; H01L 25/16; H01L 27/12; H01L 33/40; H01L 33/62

(52) U.S. Cl. CPC H01L 33/10; H01L 25/0753; H01L 25/167; H01L 27/124; H01L 33/405; H01L 33/62

(57) ABSTRACT

Disclosed is a display device comprising a substrate, a first layer provided over the substrate, a light emitting element provided over the first layer, a first planarization layer over the first layer and covering a side surface of the light emitting element and having a first refractive index, a second planarization layer over the first planarization layer and having a second refractive index, and a bank over the second planarization layer, wherein the first planarization layer has a moat spaced apart from the light emitting element and surrounds at least a portion of the light emitting element.

### CROSS-REFERENCE TO RELATED APPLICATION

This application claims the benefit of and priority to Republic of Korea Patent Application No. 10-2023-0042723, filed on Mar. 31, 2023, which is hereby incorporated by reference in its entirety.

### TECHNICAL FIELD

The present disclosure relates to a display device, and more particularly, for example, without limitation, a light emitting element (e.g., diode) display device.

### DESCRIPTION OF THE RELATED ART

The display device is widely used as a display screen of a mobile device such as a laptop computer, a notebook computer, a tablet computer, a smart phone, a portable display device, and a portable information device in addition to a display screen of a television or a monitor. Among various display devices, e liquid crystal display device and organic light emitting display device display an image by using a thin film transistor as a switching element. Since the liquid crystal display device has the backlight unit, there is a limitation in design, and luminance and response speed may be reduced. Since the organic light emitting display device includes an organic material, the organic light emitting display device is vulnerable to moisture, and thus reliability and lifespan thereof may be deteriorated.

Recently, research and development of a light emitting element (e.g., diode) display device using a micro light emitting element (e.g., diode) has been conducted, and the light emitting element display device has high quality and high reliability, thereby being spotlighted as a next generation display device.

### SUMMARY

A light emitting element (e.g., a diode) display device can generate a stain on a panel due to a rapid luminance difference between a front surface and a side surface of the panel. In addition, due to a P/N electrode structure of a light emitting element (e.g., a diode), asymmetry occurs in the luminance of left and right orientation angles. Also, light emitted from the light emitting diode is absorbed in a bank adjacent to the light emitting diode, whereby it might cause a problem related to lowering of light extraction efficiency.

The present disclosure has been made in view of the above problems and other limitations associated with the related art, and it is an object of the present disclosure to provide a display device with improved light efficiency.

In accordance with an embodiment of the present disclosure, the above and other objects can be accomplished by the provision of a light emitting element display device comprising a substrate, an adhesive layer provided over the substrate, a light emitting diode provided over the adhesive layer, a first planarization layer provided over the adhesive layer and configured to cover a side surface of the light emitting diode and to have a first refractive index, a second planarization layer disposed over the first planarization layer and configured to have a second refractive index, and a bank provided over the second planarization layer, wherein the first planarization layer has a moat spaced apart from the light emitting diode and configured to surround at least a portion of the light emitting diode.

In accordance with another embodiment of the present disclosure, there is provided a light emitting diode display device comprising a light emitting diode provided over a substrate, a first planarization layer disposed over a side surface and an upper surface of the light emitting diode and configured to have a first refractive index, a moat provided over the first planarization layer and configured to include a side surface facing the light emitting diode, and a first reflective plate provided over at least a portion of the side surface of the moat.

Additional features and aspects will be set forth in part in the following description and in part will become apparent from the following description, or may be learned by practice of the inventive concepts provided herein. Other features and aspects of the inventive concepts may be realized and attained by the structure particularly pointed out, or derivable therefrom, in the written description, the claims hereof, and the appended drawings.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram illustrating a light emitting diode display device according to one exemplary embodiment of the present disclosure;

FIG. 2A is a cross-sectional view illustrating a portion of a light emitting diode display device according to one exemplary embodiment of the present disclosure;

FIG. 2B is a perspective view illustrating a tiling display device according to one exemplary embodiment of the present disclosure;

FIG. 3A is an enlarged plan view illustrating a light emitting diode display device according to one exemplary embodiment of the present disclosure;

FIG. 3B is an enlarged plan view illustrating a subpixel of a light emitting diode display device according to one exemplary embodiment of the present disclosure;

FIG. 3C is an enlarged plan view illustrating a light emitting diode display device in which a moat is deformed according to one exemplary embodiment;

FIG. 3D is an enlarged plan view illustrating a subpixel of a light emitting diode display device in which a moat is deformed according to one exemplary embodiment;

FIG. 4A is a cross-sectional view illustrating an example along A-A′ of FIGS. 3A and 3C according to one exemplary embodiment;

FIG. 4B is a cross-sectional view illustrating an example along B-B′ of FIGS. 3A and 3C according to one exemplary embodiment;

FIG. 5A is an enlarged plan view illustrating a light emitting diode display device according to another exemplary embodiment of the present disclosure;

FIG. 5B is an enlarged plan view illustrating a subpixel of a light emitting diode display device according to another exemplary embodiment of the present disclosure;

FIG. 5C is an enlarged plan view illustrating a light emitting diode display device in which a moat is modified according to another exemplary embodiment;

FIG. 5D is an enlarged plan view illustrating a subpixel of a light emitting diode display device in which a moat is modified according to another exemplary embodiment;

FIG. 6 is a cross-sectional view illustrating an example along A-A′ of FIGS. 5A and 5C according to an exemplary embodiment;

FIG. 7 is a view illustrating an example of an optical path in a display device according to exemplary embodiments of the present disclosure;

FIGS. 8A and 8B are diagrams illustrating simulation results for each exemplary embodiment of the present disclosure; and

FIG. 9 is a cross-sectional view of a light emitting diode display device in which a moat is not provided according to an exemplary embodiment.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

Shapes, dimensions (e.g., sizes, lengths, widths, heights, thicknesses, locations, radii, diameters, and areas), ratios, angles, numbers, the number of elements, and the like disclosed herein, including those illustrated in the drawings are merely examples, and thus the present disclosure is not limited to the illustrated details. It is, however, noted that the relative dimensions of the components illustrated in the drawings are part of the present disclosure. Like reference numerals refer to like elements throughout. In the following description, when the detailed description of the relevant known function or configuration is determined to unnecessarily obscure the important point of the present disclosure, the detailed description will be omitted. In the case in which “comprise”, “have”, “include”, “contain,” “constitute,” “made of,” “formed of,” “composed of,” or the like described in the present specification are used, one or more other parts may also be present unless a term such as “only” or the like is used. The terms used in the present disclosure are merely used in order to describe particular example embodiments, and are not intended to limit the scope of the present disclosure. The terms in a singular form may include plural forms unless noted to the contrary. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompass all the meanings of the term “can.”

An element, feature, or corresponding information (e.g., a level, range, dimension, size, or the like) is construed as including an error region although there is no explicit description thereof. An error or tolerance range may be caused by various factors (e.g., process factors, internal or external impact, noise, or the like). In interpreting a numerical value, the value is interpreted as including an error range unless explicitly stated otherwise.

In describing a positional relationship, for example, when the positional order is described as “on,” “on top of,” “over,” “under,” “above,” “below,” “beneath”, “near,” “close to,” “adjacent to,” “beside,” and “next,” or the like, the case of no contact therebetween may be included, unless a term such as “just”, “immediate(ly),” “close(ly),” or “direct(ly)” is used.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In the drawings, the same or similar elements are denoted by the same reference numerals even though they are depicted in different drawings.

The area and thickness of each component shown in the drawing are shown for convenience of explanation. This invention is not necessarily limited to the area and thickness of the illustrated configuration.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Hereinafter, a light emitting element (e.g., a diode) display device according to the present disclosure will be described with reference to the accompanying drawings.

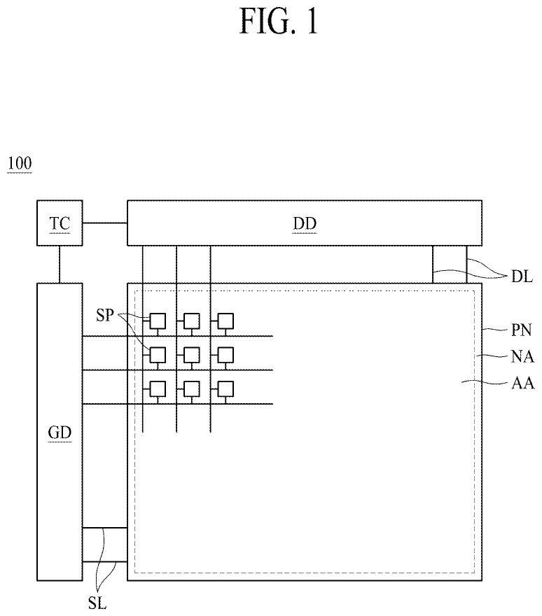

FIG. 1 is a schematic diagram illustrating a light emitting diode display device according to one embodiment of the present disclosure. For convenience of description, FIG. 1 illustrates only a display panel PN, a gate driver GD, a data driver DD, and a timing controller TC among various components of the light emitting diode display device 100.

Referring to FIG. 1, the display device 100 can include the display panel PN having a plurality of subpixels SP, the gate driver GD and data driver DD for supplying various signals to the display panel PN, and the timing controller TC for controlling the gate driver GD and data driver DD.

The gate driver GD can sequentially supply a plurality of scan signals to a plurality of gate line GL (e.g., scan lines SL) according to a plurality of gate control signals provided from the timing controller TC. In FIG. 1, one gate driver GD can be disposed to be spaced apart from one side of the display panel PN, but the number and arrangement of the gate drivers GD are not limited thereto. For example, there may be two or more gate drivers disposed to be spaced apart from one or more (e.g., upper, lower, left, right) sides of the display panel PN. The gate driver GD may be provided in a bezel region BZ, which does not display an image, outside a screen in the display panel PN.

The data driver DD can receive image data DATA from the timing controller TC, convert image data input from the timing controller TC into a data voltage of an analog type by using a reference gamma voltage according to a plurality of data control signals provided from the timing controller TC. The data driver DD can supply the converted data voltage to a plurality of data lines DL at a timing when the scan signal is applied through the gate line GL, to allow each subpixel SP to represent brightness according to the image data.

The timing controller TC can align the image data input from the outside and can supply the image data to the data driver DD. The timing controller TC can generate the gate control signal and the data control signal by using a synchronization signal input from the outside, for example, a dot clock signal, a data enable signal, and a horizontal/vertical synchronization signal through a receiving circuit such as an LVDS or TMDS interface connected with a host system. The timing controller TC can control operations of the gate driver GD and the data driver DD by respectively supplying the gate control signal and the data control signal to the gate driver GD and the data driver DD.

The display panel PN can be a component for displaying an image to a user, and the display panel PN can include a display area AA for displaying an image and a non-display area NA (also called a bezel area) outside the display area AA (e.g., surrounding the display area AA).

A plurality of pixels PX including the plurality of subpixels SP and a circuit for driving the plurality of subpixels SP can be disposed in the display area AA. The plurality of subpixels SP can be a minimum unit constituting the display area AA, and the ‘n’ (e.g., 4, 6, 9 and the like) subpixels SP can constitute one pixel PX. A light emitting diode LED and a thin film transistor TFT for driving the light emitting diode LED can be disposed for each of the plurality of subpixels SP. For example, a light emitting diode LED can be an organic light emitting diode, an inorganic light emitting diode, a micro light emitting diode or the like.

A plurality of signal lines for transmitting various signals to the plurality of subpixels SP can be disposed in the display area AA. For example, the plurality of signal lines can include the plurality of data lines DL for supplying the data voltage to each of the plurality of subpixels SP, and the plurality of gate (e.g., scan) lines SL for supplying a gate voltage to each of the plurality of subpixels SP. The plurality of scan lines SL can extend in one direction in the display area AA and can be connected to the plurality of subpixels SP. The plurality of data lines DL can extend in a direction different from the one direction in the display area AA and can be connected with the plurality of subpixels SP. A subpixel may be disposed in intersection portions (or intersection regions) where data lines and gate lines cross each other. In addition, a first power line, a second power line, a touch line, an initialization line, a reset line and the like can be further disposed in the display area AA, but not limited thereto.

The non-display area NA can be an area in which an image is not displayed, and can be provided to be adjacent to (e.g., surround) the display area AA. A link wiring and/or a pad electrode for transmitting the signal to the subpixel SP of the display area AA and/or a circuit such as driving ICs of a gate driver IC and a data driver IC can be arranged in the non-display area NA.

Meanwhile, the non-display area NA can be disposed over a rear surface of the display panel PN, that is, a surface without the subpixel SP or can be omitted, but not limited to what is illustrated in the drawings.

A driving unit such as the gate driver GD, the data driver DD, and the timing controller TC can be connected with the display panel PN in various ways. For example, the gate driver GD may be connected with the display panel PN in the tape automated bonding (TAB) type, or connected with a conductive pad such as a bonding pad of the display panel PN in the chip on glass (COG) type or the chip on panel (COP) type, or connected with the display panel PN in the chip on film (COF) type. Alternatively, the gate driver GD can be mounted on the non-display area NA by a Gate In Panel GIP manner, and the gate driver GD can be mounted between each of the plurality of subpixels SP in the display area AA by a Gate In Active area GIA manner. For example, the data driver DD may be implemented as a source drive circuit or a source drive integrated circuit (IC). The data driver DD may be connected with the bonding pads of the display panel PN using tape automated bonding (TAB), chip on panel (COP), or chip on glass (COG) methods, or may be implemented in a chip on film (COF) method and connected with the display panel PN, or directly arranged on the display panel PN, and in some cases, it may be integrated and arranged within the display panel PN. For example, the data driver DD and the timing controller TC can be provided over a separate flexible film and/or a printed circuit board and can be electrically connected with the display panel PN in a method of bonding the flexible film and/or the printed circuit board to the pad electrode provided in the non-display area NA of the display panel PN. If the gate driver GD is mounted in the GIP manner, and the data driver DD and the timing controller TC transmit the signal to the display panel PN through the pad electrode of the non-display area NA, it requires to secure the area of the non-display area NA for arranging the gate driver GD and the pad electrode, whereby a bezel may be increased.

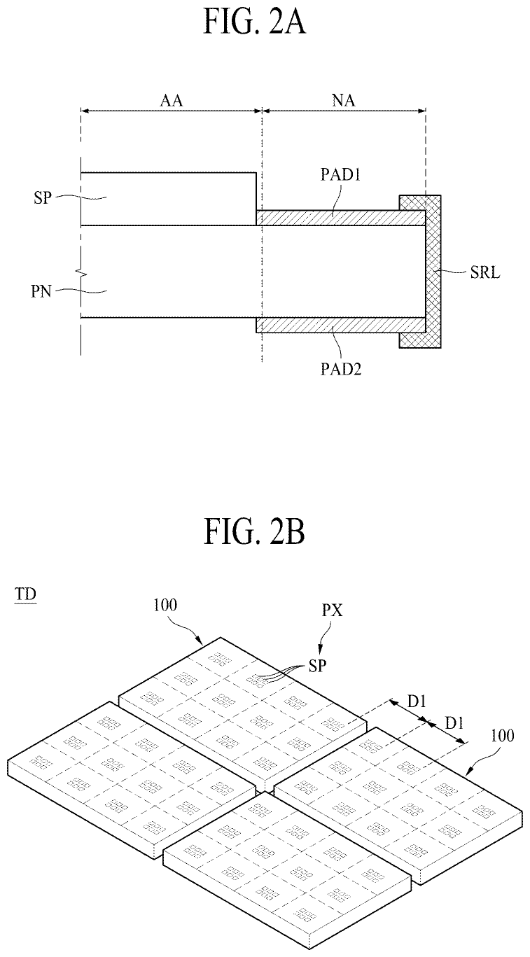

Alternatively, if the gate driver GD can be provided inside the display area AA by the GIA manner, and the flexible film and/or the printed circuit board are bonded to the rear surface of the display panel PN by forming a side wiring SRL connecting the signal line over the front surface of the display panel PN with the pad electrode over the rear surface of the display panel PN, the non-display area NA can be reduced on the front surface of the display panel PN. That is, when the gate driver GD, the data driver DD, and the timing controller TC are connected with the display panel PN in the above-described manner, it is possible to realize a zero bezel having substantially no bezel. A more detailed description thereof will be described with reference to FIGS. 2A and 2B.

FIG. 2A is a partial cross-sectional view illustrating a light emitting diode display device according to one embodiment of the present disclosure. FIG. 2B is a perspective view illustrating a tiling display device according to one embodiment of the present disclosure.

The plurality of pad electrodes for transmitting various signals to the plurality of subpixels SP can be disposed in the non-display area NA of the display panel PN. For example, the first pad electrode PAD1 for transmitting the signal to the plurality of subpixels SP can be disposed in the non-display area NA on the front surface of the display panel PN, and the second pad electrode PAD2 electrically connected with driving components such as the flexible film and/or the printed circuit board can be disposed in the non-display area NA on the rear surface of the display panel PN.

In this case, the various signal lines connected with the plurality of subpixels SP, for example, the scan line SL or data line DL, can extend from the display area AA to the non-display area NA and can be electrically connected with the first pad electrode PAD1.

Then, the side wiring SRL can be disposed along the side surface of the display panel PN. The side wiring SRL can electrically connect the first pad electrode PAD1 over the front surface of the display panel PN with the second pad electrode PAD2 over the rear surface of the display panel PN. Thus, the signal applied from the driving component over the rear surface of the display panel PN can be transmitted to the plurality of subpixels SP through the second pad electrode PAD2, the side wiring SRL, and the first pad electrode PAD1. Therefore, it is possible to reduce or minimize the area of the non-display area NA in the display panel PN by forming a signal transmission path between the front surface of the display panel PN and the side and rear surfaces of the display panel PN.

Referring to FIG. 2B, the tiling display device TD having a large screen can be implemented by connecting the plurality of light emitting diode display devices 100. As shown in FIG. 2A, when implementing the tiling display device TD by using the light emitting diode display device 100 with the minimized bezel, it is possible to reduce or minimize a seam area corresponding to an area in which an image is not displayed between the two adjacent light emitting diode display devices 100.

For example, the plurality of subpixels SP can constitute one pixel PX, and a distance D1 between the outermost pixel PX of one light emitting diode display device 100 and the outermost pixel PX of another light emitting diode display device 100 adjacent thereto can be implemented to be the same as a distance D1 between the pixels PX in one light emitting diode display device 100. Therefore, according as the seam area of the light emitting diode display device 100 is reduced, the distance between adjacent outermost pixels PX of the two adjacent light emitting diode display devices 100 becomes constant, thereby implementing the tiling display device TD without the sense of difference in the seam area.

FIGS. 2A and 2B can illustrate examples of the present disclosure. The light emitting diode display device 100 according to one embodiment of the present disclosure can be a light emitting diode display device 100 in which a bezel exists, but not limited thereto.

Hereinafter, the X-axis represents a direction parallel to the scan line, the Y-axis represents a direction parallel to the data line, and the Z-axis represents a height direction of the light emitting diode display device 100.

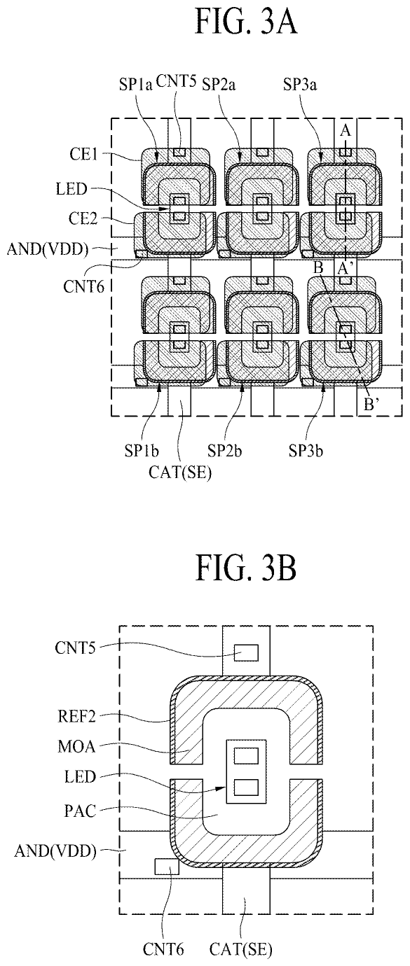

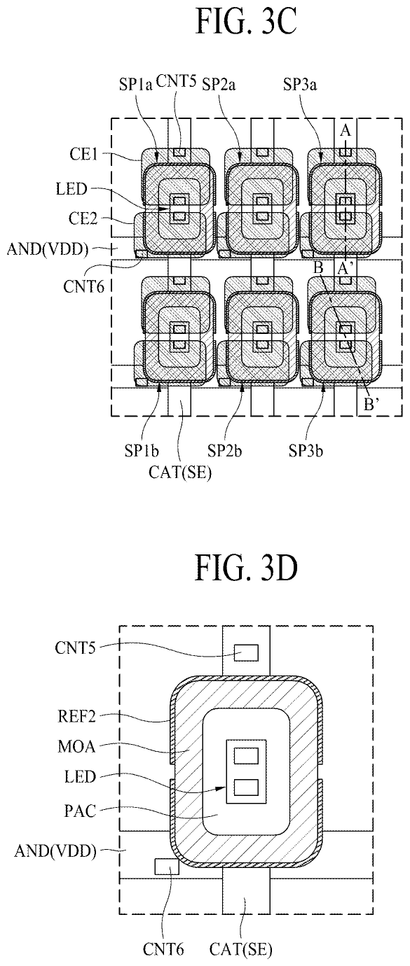

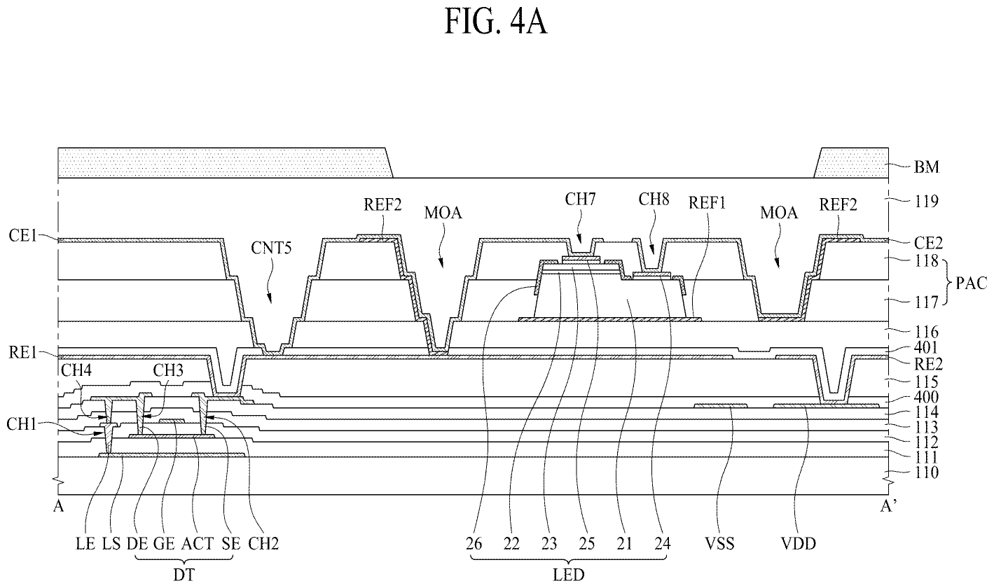

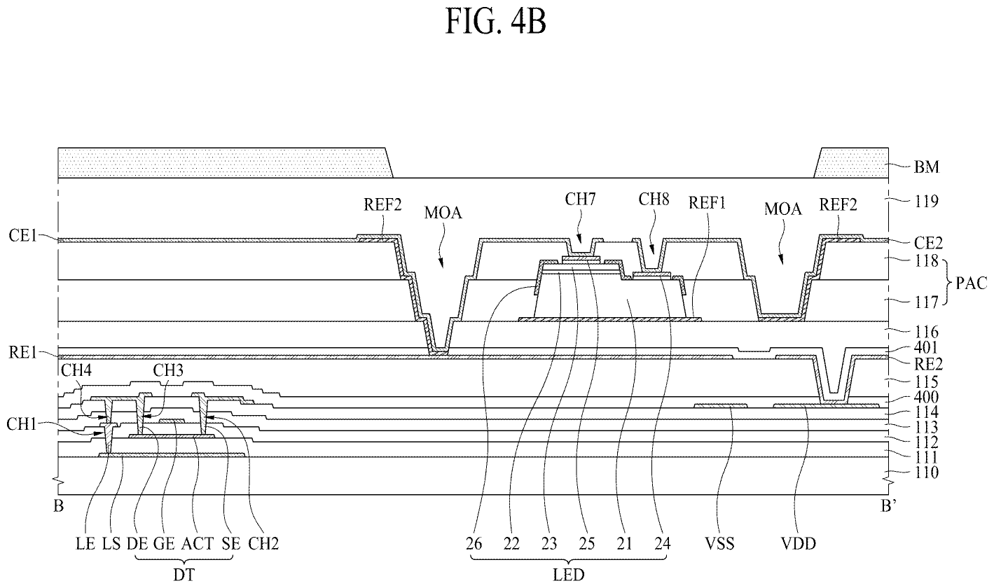

FIG. 3A is an enlarged plan view illustrating a light emitting diode display device according to one exemplary embodiment of the present disclosure. FIG. 3B is an enlarged plan view illustrating a subpixel of a light emitting diode display device according to one exemplary embodiment of the present disclosure. FIG. 3C is an enlarged plan view illustrating a light emitting diode display device in which a moat is deformed according to one exemplary embodiment of the present disclosure. FIG. 3D is an enlarged plan view illustrating a subpixel of a light emitting diode display device in which a moat is deformed according to one embodiment of the present disclosure. FIG. 4A is a cross-sectional view along A-A′ of FIGS. 3A and 3C according to one exemplary embodiment of the present disclosure. FIG. 4B is a cross-sectional view along B-B′ of FIGS. 3A and 3C according to one exemplary embodiment of the present disclosure.

Referring to FIGS. 1 and 3A to 3D, a display panel PN can include a plurality of pixels PX, wherein each pixel PX includes a plurality of subpixels SP. Each of the plurality of subpixels SP can include a light emitting diode LED and a pixel circuit to independently emit light. For example, the first subpixel SP1 can be a red subpixel, the second subpixel SP2 can be a green subpixel, and the third subpixel SP3 can be a blue subpixel, but not limited thereto. Each subpixel can emit light of other colors such as Cyan, Magenta, Yellow, Black, etc.

Herein, one pixel PX can include the first subpixel SP1, the second subpixel SP2, and the third subpixel SP3. In this case, each of the first subpixel SP1, the second subpixel SP2, and the third subpixel SP3 included in one pixel PX can be one or two or more. For example, one pixel PX can include two of the first subpixels SP1, two of the second subpixels SP2, and two of the third subpixels SP3. The first subpixel SP1 includes a (1-1)th subpixel SP1a and a (1-2)th subpixel SP1b, the second subpixel SP2 includes a (2-1)th subpixel SP2a and a (2-2)th subpixel SP2b, and the third subpixel SP3 can include a (3-1)th subpixel SP3a and a (3-2)th subpixel SP3b. The (1-1)th subpixel SP1a, the (2-1)th subpixel SP2a, and the (3-1)th subpixel SP3a can be disposed in the same row, and the (1-2)th subpixel SP1b, the (2-2)th subpixel SP2b, and the (3-2)th subpixel SP3b can be disposed in the same row. In one pixel PX, the number of the first subpixels SP1, the number of the second subpixels SP2 and the number of the third subpixels SP3 are not limited to be equal to each other, and can be any number as necessary. Each of the plurality of subpixels SP can be defined by a bank BM.

Referring to FIG. 4A, in each of the plurality of subpixels SP over the display panel PN of the light emitting diode display device 100 according to one embodiment of the present disclosure, there are a substrate 110, a light shielding layer LS, a buffer layer 111, a gate insulating layer 112, an auxiliary electrode LE, a first insulating interlayer 113, a second insulating interlayer 114, a third insulating interlayer 400, a first planarization layer 115, a fourth insulating interlayer 401, an adhesive layer 116, a second planarization layer 117, a third planarization layer 118, a driving transistor DT, a light emitting diode LED, a plurality of reflective electrodes RE, a plurality of reflective plates REF, a plurality of first connection electrodes CE1, a second connection electrode CE2, and a bank BM. Layers or elements included in each subpixel are not limited to those listed as above, some of them can be combined, some of them can be omitted, and additional layers and/or elements can be included.

The substrate 110 is configured to support various components included in the light emitting diode display device 100, and the substrate 110 can include an insulating material. For example, the substrate 110 can include glass or resin. Also, the substrate 110 can include polymer or plastic, or can include a material having flexibility. For example, the substrate 410 may be formed of at least one selected from the group consisting of polyethylene terephthalate (PET), polybutylene terephthalate (PBT), polysilane, polysiloxane, polysilazane, polycarbosilane, polyacrylate, polymethacrylate, polymethylacrylate, polymethylmetacrylate, polyethylacrylate, polyethylmetacrylate, cyclic olefin copolymer (COC), cyclic olefin polymer (COP), polyethylene (PE), polypropylene (PP), polyimide (PI), polymethylmethacrylate (PMMA), polystyrene (PS), polyacetal (POM), polyether ether ketone (PEEK), polyester sulfone (PES), polytetrafluoroethylene (PTFE), polyvinyl chloride (PVC), polycarbonate (PC), polyvinylidene fluoride (PVDF), perfluoroalkyl polymer (PFA), styrene acrylonitrile polymer (SAN), and combinations thereof. The light emitting diode display device 100 according to one exemplary embodiment of the present disclosure can be configured in a top emission method in which light is emitted toward an upper direction. Alternatively, the light emitting diode display device 100 can be configured in a bottom emission method in which light is emitted toward a lower direction. Therefore, the substrate 110 can include an opaque material or a transparent material.

The light shielding layer LS can be disposed in each of the plurality of subpixels SP over the substrate 110. The light shielding layer LS can block light incident from a lower portion of the substrate 110 to an active layer ACT of the driving transistor DT. The display panel PN of the display device 100 according to one exemplary embodiment of the present disclosure can reduce or minimize a leakage current by blocking the light incident on the active layer ACT of the driving transistor DT using the light shielding layer LS. The light shielding layer LS may include a single layer or multi-layer made of any one of molybdenum (Mo), aluminum (Al), chromium (Cr), gold (Au), titanium (Ti), nickel (Ni), neodymium (Nd) and copper (Cu), or their alloy.

The buffer layer 111 can be disposed over the substrate 110 and the light shielding layer LS. The buffer layer 111 can reduce penetration of moisture, impurities or the like through the substrate 110. For example, the buffer layer 111 can be composed of a single layer or multiple layers of silicon oxide SiOx, silicon nitride SiNx, silicon oxynitride SiONx or the like, but not limited thereto. However, the buffer layer 111 can be omitted depending on the type of the substrate 110 or the type of transistor, but not limited thereto.

The driving transistor DT can be disposed over the buffer layer 111. The driving transistor DT can include an active layer ACT, a gate electrode GE, a source electrode SE, and a drain electrode DE.

In detail, the active layer ACT can be disposed over the buffer layer 111. The active layer ACT can include a semiconductor material such as oxide semiconductor, amorphous silicon, or polysilicon, but is not limited thereto.

The gate insulating layer 112 can be disposed over the active layer ACT. The gate insulating layer 112 is an insulating layer for insulating the active layer ACT and the gate electrode GE from each other. The gate insulating layer 112 can be composed of a single layer or a multi-layer of silicon oxide SiOx, silicon nitride SiNx, silicon oxynitride SiONx or the like, but not limited thereto.

The gate electrode GE can be disposed over the gate insulating layer 112. The gate electrode GE can include a conductive material, for example, copper Cu, aluminum Al, molybdenum Mo, nickel Ni, titanium Ti, chromium Cr, or an alloy thereof, but not limited thereto.

The first insulating interlayer 113 and the second insulating interlayer 114 can be disposed over the gate electrode GE. In the first insulating interlayer 113 and the second insulating interlayer 114, a third contact hole CH3 and a second contact hole CH2 can be provided to connect the source electrode SE and the drain electrode DE with the active layer ACT, respectively. The first insulating interlayer 113 and the second insulating interlayer 114 are insulating layers for protecting the components under the first insulating interlayer 113 and the second insulating interlayer 114. The first insulating interlayer 113 and the second insulating interlayer 114 can be composed of a single layer or multilayers of silicon oxide SiOx, silicon nitride SiNx, silicon oxynitride SiONx or the like, but not limited thereto.

The source electrode SE and the drain electrode DE are disposed over the second insulating interlayer 114 and can be electrically connected with the active layer ACT. The source electrode SE and the drain electrode DE can include a conductive material, for example, copper Cu, aluminum Al, molybdenum Mo, nickel Ni, titanium Ti, chromium Cr, or an alloy thereof, but not limited thereto.

Meanwhile, the present disclosure illustrates that the first insulating interlayer 113 and a second insulating interlayer 114, that is, the plurality of insulating layers are disposed between the gate electrode GE and the source electrode SE/drain electrode DE. However, only one insulating layer can be disposed between the gate electrode GE and the source electrode SE/drain electrode DE, but not limited thereto.

When the plurality of insulating layers such as the first insulating interlayer 113 and the second insulating interlayer 114 are disposed between the gate electrode GE and the source electrode SE/drain electrode DE, as shown in the drawings, an electrode can be additionally provided between the first insulating interlayer 113 and the second insulating interlayer 114. The additionally provided electrode together with other components disposed below the first insulating interlayer 113 or above the second insulating interlayer 114 can form a capacitor.

The auxiliary electrode LE can be further disposed over the gate insulating layer 112. The auxiliary electrode LE can be an electrode for electrically connecting the light shielding layer LS disposed under the buffer layer 111 with any one of the source electrode SE and the drain electrode DE over the second insulating interlayer 114. For example, the light shielding layer LS can be electrically connected with any one of the source electrode SE and the drain electrode DE through the auxiliary electrode LE and cannot operate as a floating gate. When the light shielding layer LS is floated without being connected with other electrodes, a threshold voltage of the driving transistor DT may be changed by the floated light shielding layer LS. The display panel PN of the light emitting diode display device 100 according to one exemplary embodiment of the present disclosure electrically connects the light shielding layer LS with any one of the source electrode SE and the drain electrode DE, so that it is possible to reduce or minimize the change in the threshold voltage of the driving transistor DT. In the drawings, the light shielding layer LS is connected with the drain electrode DE through a first contact hole CH1 passing through the buffer layer 111 and the gate insulating layer 112, and a fourth contact hole CH4 passing through the first insulating interlayer 113 and the second insulating interlayer 114. However, the light shielding layer LS can be connected with the source electrode SE, but not limited thereto.

The source electrode SE, the drain electrode DE, a first power line VDD, and a second power line VSS can be disposed over the second insulating interlayer 114. The first power line VDD is electrically connected with the light emitting diode LED together with the driving transistor DT, to thereby make the light emitting diode LED emit light. The first power line VDD and the second power line VSS can include a conductive material, for example, copper Cu, aluminum Al, molybdenum Mo, nickel Ni, titanium Ti, chromium Cr, or an alloy thereof, but not limited thereto.

The third insulating interlayer 400 can be disposed over the driving transistor DT, the first power line VDD, and the second power line VSS. The third insulating interlayer 400 is an insulating layer for protecting a configuration below the third insulating interlayer 400, and the third insulating interlayer 400 can be composed of a single layer or multilayers of silicon oxide SiOx, silicon nitride SiNx, silicon oxynitride SiONx or the like, but not limited thereto.

The first planarization layer 115 can be disposed over the third insulating interlayer 400. The first planarization layer 115 can planarize an upper portion of the substrate 110 on which the driving transistor DT is disposed. The first planarization layer 115 can include a single-layered structure or a multi-layered structure, and the first planarization layer 115 can include photoresist or acryl-based organic material, but not limited thereto. For example, the first planarization layers 115 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The plurality of reflective electrodes RE1 and RE2 are spaced apart from each other and can be disposed over the first planarization layer 115. The plurality of reflective electrodes RE1 and RE2 electrically connect the light emitting diode LED with the first power line VDD and the driving transistor DT and can function as a reflector for reflecting light emitted from the light emitting diode LED to an upper portion of the light emitting diode LED. The plurality of reflective electrodes RE1 and RE2 include a conductive material having excellent reflection characteristics, whereby the plurality of reflective electrodes RE1 and RE2 can reflect light emitted from the light emitting diode LED toward an upper portion of the light emitting diode LED. For example, the reflective electrode may be formed of aluminum (Al), copper (Cu), silver (Ag), nickel (Ni), or an alloy of these elements, preferably, APC (silver/palladium/copper alloy).

The plurality of reflective electrodes RE1 and RE2 can include the first reflective electrode RE1 and the second reflective electrode RE2. The first reflective electrode RE1 can electrically connect the driving transistor DT and the light emitting diode LED to each other. The first reflective electrode RE1 can be connected with the source electrode SE or drain electrode DE of the driving transistor DT through the contact hole provided in the first planarization layer 115. The first reflective electrode RE1 can be electrically connected with a P-type electrode 25 and a P-type semiconductor layer 23 of the light emitting diode LED through a first connection electrode CE1 to be described later.

The second reflective electrode RE2 can electrically connect the first power line VDD and the light emitting diode LED to each other. The second reflective electrode RE2 can be connected with the first power line VDD through the contact hole provided in the first planarization layer 115. The second reflective electrode RE2 can be electrically connected with an N-type electrode 24 and an N-type semiconductor layer 21 of the light emitting diode LED through a second connection electrode CE2 to be described later.

The fourth insulating interlayer 401 can be disposed over the plurality of reflective electrodes RE1 and RE2. The fourth insulating interlayer 401 is an insulating layer for protecting a configuration below the fourth insulating interlayer 401, and the fourth insulating interlayer 401 can be composed of a single layer or multiple layers of silicon oxide SiOx, silicon nitride SiNx, silicon oxynitride SiONx or the like, but not limited thereto.

The adhesive layer 116 can be disposed over the fourth insulating interlayer 401. The adhesive layer 116 is coated on the entire surface of the substrate 110 and is configured to fix (e.g., attach) the light emitting diode LED disposed over the adhesive layer 116. For example, the adhesive layer 116 can be a thermosetting material or a photo curing material and can be selected from any one among adhesive copolymer, epoxy resist, UV resin, polyimide-based material, acrylate-based material, urethane-based material, and polydimethylsiloxane PDMS based material, but not limited thereto.

The plurality of light emitting diodes LED are respectively disposed in the plurality of subpixels SP over the adhesive layer 116. The plurality of light emitting diodes LED can include elements for emitting light by a current, for example, light emitting diodes LED for emitting red light, green light, blue light, and the like, and the plurality of light emitting diodes LED can implement light of various colors including white by combination thereof. For example, the plurality of light emitting diodes LED can be organic light emitting diodes LED, inorganic light emitting diodes LED, micro light emitting diodes LED or the like, but not limited thereto.

Referring to FIGS. 4A and 4B, the light emitting diode LED includes an N-type semiconductor layer 21, a light emitting layer 22, a P-type semiconductor layer 23, an N-type electrode 24, a P-type electrode 25, and an encapsulation film 26.

The N-type semiconductor layer 21 can be disposed over the adhesive layer 116, and the P-type semiconductor layer 23 can be disposed over the N-type semiconductor layer 21. The N-type semiconductor layer 21 can be formed by doping N-type impurities to a specific material, and the P-type semiconductor layer 23 can be formed by doping P-type impurities to a specific material. For example, each of the N-type semiconductor layer 21 and the P-type semiconductor layer 23 can be a layer doped with N-type and P-type impurities in a material such as gallium nitride GaN, indium aluminum phosphide InAlP, gallium arsenide GaAs, or the like. The P-type impurities can be magnesium, zinc Zn, beryllium Be, or the like, and the N-type impurities can be silicon Si, germanium, tin Sn, or the like, but not limited thereto.

The light emitting layer 22 can be disposed between the N-type semiconductor layer 21 and the P-type semiconductor layer 23. The light emitting layer 22 can emit light by receiving holes and electrons from the N-type semiconductor layer 21 and the P-type semiconductor layer 23. The light emitting layer 22 can have a single-layered structure (e.g., a single quantum well SQW structure) or a multi-quantum well MQW structure. For example, the light emitting layer 22 can include a nitride semiconductor, for example, indium gallium nitride InGaN or gallium nitride GaN, but not limited thereto.

The N-type electrode 24 can be disposed over the N-type semiconductor layer 21. The N-type electrode 24 can be an electrode for electrically connecting the first power line VDD and the N-type semiconductor layer 21. The N-type electrode 24 can be disposed over an upper surface of the N-type semiconductor layer 21 exposed from the light emitting layer 22 and the P-type semiconductor layer 23. For example, the N-type electrode 24 is arranged along the circumference of the upper surface of the N-type semiconductor layer 21 and is configured to have a circular shape on a plan, without being limited thereto, and can have any shape on a plan. The N-type electrode 24 can include a conductive material, for example, a transparent conductive material such as Indium Tin Oxide ITO or Indium Zinc Oxide IZO or the like, or an opaque conductive material such as aluminum (Al), chrome (Cr), molybdenum (Mo), tungsten (W), magnesium (Mg), titanium Ti, gold Au, silver Ag, copper Cu, or an alloy thereof, but not limited thereto.

The P-type electrode 25 can be disposed over the P-type semiconductor layer 23. The P-type electrode 25 can be disposed over an upper surface of the P-type semiconductor layer 23. The P-type electrode 25 is an electrode for electrically connecting the driving transistor DT and the P-type semiconductor layer 23. The P-type electrode 25 can include a transparent conductive material such as a conductive material, for example, Indium Tin Oxide ITO or Indium Zinc Oxide IZO, or an opaque conductive material such as aluminum (Al), chrome (Cr), molybdenum (Mo), tungsten (W), magnesium (Mg), titanium Ti, gold Au, silver Ag, copper Cu, or an alloy thereof, but not limited thereto.

Then, the encapsulation film 26 can be disposed to surround at least a portion of the N-type semiconductor layer 21, the light emitting layer 22, the P-type semiconductor layer 23, the N-type electrode 24, and the P-type electrode 25. The encapsulation film 26 can include an insulating material to protect the N-type semiconductor layer 21, the light emitting layer 22, and the P-type semiconductor layer 23. A contact hole exposing the N-type electrode 24 and the P-type electrode 25 can be provided in the encapsulation film 26. The first connection electrode CE1 and the P-type electrode 25 can be electrically connected to each other, and the second connection electrode CE2 and the N-type electrode 24 can be electrically connected to each other.

A first reflective plate REF1 can be disposed over a lower portion of the plurality of light emitting diodes LED. The first reflective plate REF1 can be distinguished from the plurality of reflective electrodes RE1 and RE2 and can be disposed between the light emitting diode LED and the plurality of reflective electrodes RE1 and RE2. The first reflective plate REF1 can include an opaque metal material such as aluminum (Al), chrome (Cr), molybdenum (Mo), tungsten (W), magnesium (Mg), titanium Ti, gold Au, silver Ag, copper Cu, or an alloy thereof.

A planarization layer PAC can be disposed over the plurality of light emitting diodes LED. The planarization layer PAC can include the second planarization layer 117 and the third planarization layer 118. The second planarization layer 117 and the third planarization layer 118 can be disposed to cover the plurality of light emitting diodes LED and can be configured to fix and protect the plurality of light emitting diodes LED. The second planarization layer 117 can have a first refractive index. The third planarization layer 118 can have a second refractive index. The first refractive index can be the same as or different from the second refractive index. The second planarization layer 117 and the third planarization layer 118 can be provided in a single layer or multilayers and can include photoresist or acryl-based organic material, but not limited thereto. For example, the second planarization layers 117 and the third planarization layer 118 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto. Although it has been described herein that the second planarization layer 117 and the third planarization layer 118 are disposed to cover the plurality of light emitting diodes LED, the planarization layer covering the plurality of light emitting diodes can include a single layer, but not limited thereto. In addition, the third planarization layer 118 can be provided only in an area adjacent to the light emitting diode LED.

The planarization layer PAC can be provided with a moat MOA. The moat MOA can be provided to correspond to each of the plurality of light emitting diodes LED. The moat MOA can be provided in a region adjacent to the corresponding light emitting diode LED and can be spaced apart from the corresponding light emitting diode LED. The moat MOA can include a side facing the light emitting diode LED.

The moat MOA can be formed by removing a portion of at least one insulating layer provided in an area adjacent to the light emitting diode LED. The moat MOA is formed by depositing the third planarization layer 118 and removing at least one of a fourth insulating interlayer 401, an adhesive layer 116, a second planarization layer 117, and a third planarization layer 118 by using a photolithography process and a dry etch process.

A depth of the moat MOA can vary depending on the location. Specifically, a depth in a portion of moat MOA overlapped with the first connection electrode CE1 can be different from a depth in a portion of moat MOA overlapped with the second connection electrode CE2. For example, as shown in FIGS. 4A and 4B, the portion of moat MOA overlapped with the first connection electrode CE1 can be formed by removing a portion of the fourth insulating interlayer 401, the adhesive layer 116, the second planarization layer 117, and the third planarization layer 118. On the other hand, the portion of moat MOA overlapped with the second connection electrode CE2 can be formed by removing a portion of the second planarization layer 117 and the third planarization layer 118.

The moat MOA can include internal structure with lower surfaces and side surfaces facing the light emitting diode LED. The side surfaces of the moat MOA can have step differences, but not limited thereto. A second reflective plate REF2 can be provided over at least a portion of the side surface positioned farther from the light emitting diode LED among the side surfaces of the moat MOA. The moat MOA can include the first side surface and the second side surface facing each other. The first side surface can be disposed adjacent to the light emitting diode LED. The first side surface can be a first inclined surface in which a distance to the light emitting diode LED gradually decreases from its lower portion to its upper portion. The second side surface can be disposed farther from the light emitting diode LED as compared to the first side surface. The second side surface can be a second inclined surface in which a distance to the light emitting diode LED gradually increases from its lower portion to its upper portion. The second reflective plate REF2 can be provided to cover at least a portion of the second side surface of the moat MOA. For example, the second reflective plate REF2 can be provided to cover the entire surface of the second side surface of the moat MOA. For example, the second reflective plate REF2 can be provided to cover an upper surface of each step connected with the second side surface of the moat MOA and the lower surface of the moat MOA. The second reflective plate REF2 can extend from the second side surface of the moat MOA and can also be provided over at least a portion of an upper surface of the third planarization layer 118.

The moat MOA can be provided to surround at least a portion of the light emitting diode LED in a region adjacent to the light emitting diode LED. In one exemplary embodiment of the present disclosure, the moat MOA can be provided to surround a portion of the light emitting diode LED, as shown in FIGS. 3A and 3B. The moat MOA can include a first moat corresponding to the portion of moat MOA overlapped with the first connection electrode CE1, and a second moat corresponding to the portion of moat MOA overlapped with the second connection electrode CE2. The first moat and the second moat are spaced apart and can be separated from each other. In this case, the second reflective plate REF2 provided in the portion of moat MOA overlapped with the first connection electrode CE1 can be spaced apart from the second reflective plate REF2 provided in the portion of moat MOA overlapped with the second connection electrode CE2, whereby they can be electrically separated from each other.

In another exemplary embodiment of the present disclosure, the moat MOA can be provided to surround all portions of the light emitting diode LED, as shown in FIGS. 3C and 3D. The moat MOA can include a first moat corresponding to the portion of moat MOA overlapped with the first connection electrode CE1, and a second moat corresponding to the portion of moat MOA overlapped with the second connection electrode CE2. The first moat and the second moat can be connected to each other. For example, the moat MOA can have a ring shape, or can have a rectangular shape or a square having angled corners or smoothly curved edges in a plan view. In this case, the second reflective plate REF2 provided in the portion of moat MOA overlapped with the first connection electrode CE1 can be spaced apart from the second reflective plate REF2 provided in the portion of moat MOA overlapped with the second connection electrode CE2, whereby they can be electrically separated from each other. Referring to FIGS. 3A to 3D, a fifth contact hole CNT5 and a sixth contact hole CNT6 can be provided at a position separate from the moat MOA.

Referring once again to FIG. 4A, the plurality of first connection electrodes CE1 and the plurality of second connection electrodes CE2 can be provided after forming the second reflective plate REF2.

The first connection electrode CE1 can be disposed in each of the plurality of subpixels SP. The first connection electrode CE1 can be an electrode for electrically connecting the light emitting diode LED and the driving transistor DT to each other. The first connection electrode CE1 can be connected with the first reflective electrode RE1 through the fifth contact hole CNT5 provided in the third planarization layer 118, the second planarization layer 117, the adhesive layer 116, and the fourth insulating interlayer 401. Thus, the first connection electrode CE1 can be electrically connected with any one of the source electrode SE and the drain electrode DE of the driving transistor DT through the first reflective electrode RE1. The first connection electrode CE1 can be connected with the P-type electrode 25 in each of the plurality of light emitting diodes LED through the contact hole provided in the third planarization layer 118. Thus, the first connection electrode CE1 can electrically connect the driving transistor DT with the P-type electrode 25 and the P-type semiconductor layer 23 of the plurality of light emitting diodes LED.

The second connection electrode CE2 can be an electrode for electrically connecting the light emitting diode LED and the first power line VDD to each other. The second connection electrode CE2 can be connected with the second reflective electrode RE2 through the contact hole (not shown) provided in the third planarization layer 118, the second planarization layer 117, the adhesive layer 116, and the fourth insulating interlayer 401. Thus, the second connection electrode CE2 can be electrically connected to the first power line VDD through the second reflective electrode RE2. The second connection electrode CE2 can be connected with the N-type electrode 24 of each of the plurality of light emitting diodes LED through the contact hole provided in the third planarization layer 118. Thus, the second connection electrode CE2 can electrically connect the first power line VDD with the N-type electrode 24 and the N-type semiconductor layer 21 in each of the plurality of light emitting diodes LED.

Meanwhile, the first connection electrode CE1 for connecting the driving transistor DT disposed in each of the plurality of subpixels SP and the light emitting diode LED to each other can be individually disposed in each of the plurality of subpixels SP. The second connection electrode CE2 disposed in each of the plurality of subpixels SP and configured to connect the first power line VDD with the light emitting diode LED can be connected to each other. That is, since a power voltage of the first power line VDD is commonly applied to all of the plurality of light emitting diodes LED in the plurality of subpixels SP, one of the second connection electrode CE2 can be disposed in all of the plurality of subpixels SP.

The fourth planarization layer 119 can be provided over the first and second connection electrodes CE1 and CE2. The fourth planarization layer 119 can provide a flat surface by filling the moat MOA. The fourth planarization layer 119 can be provided to fill the fifth contact hole CNT5 over the first connection electrode CE1 provided in the fifth contact hole CNT5. In addition, the fourth planarization layer 119 can be provided to fill the eighth contact hole CH8 over the second connection electrode CE2 provided in the eighth contact hole CH8.

The fourth planarization layer 119 can include an organic film such as one or more of acryl resin, epoxy resin, phenolic resin, polyamide resin, polyimide resin, unsaturated polyesters resin, polyphenylene resin, polyphenylene sulfides resin, and benzocyclobutene. The fourth planarization layer 119 can have a third refractive index.

Referring once again to FIGS. 4A and 4B, the bank BM can be provided over the fourth planarization layer 119.

The bank BM can define a light emitting region for each of the subpixels SP1, SP2, and SP3. The bank BM can include an opening region corresponding to the light emitting region through which light emitted from the light emitting diode LED is emitted to the outside. The light emitted from the light emitting diode LED provided in each of the subpixels SP1, SP2, and SP3 can be emitted to the outside in the opening region of the bank BM. Accordingly, the light emitting region in each of the subpixels S1, SP2, and SP3 can correspond to the region where the bank BM is not provided.

Meanwhile, the bank BM can include an organic film such as acryl resin, epoxy resin, phenolic resin, polyamide resin, polyimide resin, and the like, and can include a black material for absorbing the light. Accordingly, the light emitted from the light emitting diode LED provided in each of the subpixels SP1, SP2, and SP3 can be absorbed in the region where the bank BM is provided, whereby the light cannot be emitted to the outside. Thus, the region where the bank BM is provided can correspond to a non-emission region. The bank BM can prevent the light emitted from the light emitting diode LED from proceeding to the adjacent subpixels SP1, SP2, and SP3, thereby preventing color mixing between the subpixels SP1, SP2, and SP3.

According to one exemplary embodiment of the present disclosure, the bank BM can be disposed in the region which is not overlapped with the moat MOA and the light emitting diode LED, to thereby minimize or reduce luminance reduction. The bank BM cannot be disposed in the region overlapped with the moat MOA.

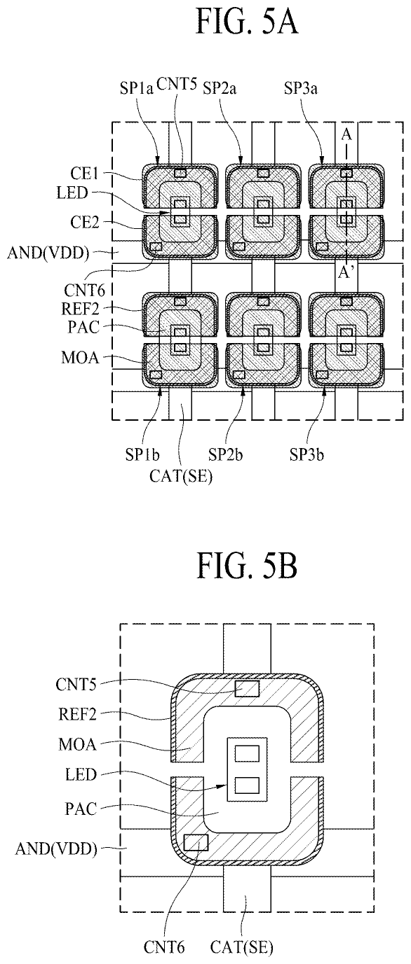

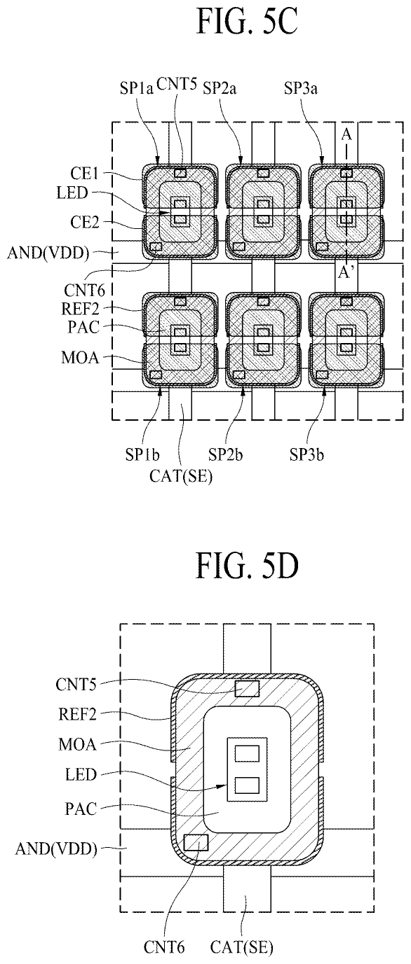

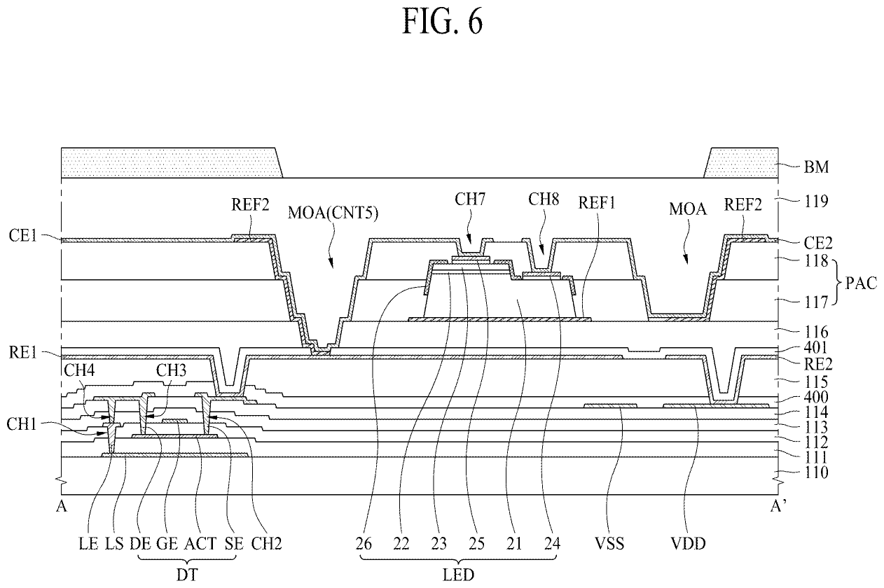

FIG. 5A is an enlarged plan view illustrating a light emitting diode display device according to another exemplary embodiment of the present disclosure. FIG. 5B is an enlarged plan view illustrating a subpixel of a light emitting diode display device according to another exemplary embodiment of the present disclosure. FIG. 5C is an enlarged plan view illustrating a light emitting diode display device in which a moat is deformed according to another exemplary embodiment of the present disclosure. FIG. 5D is an enlarged plan view illustrating a subpixel of a light emitting diode display device in which a moat is deformed according to another exemplary embodiment of the present disclosure. FIG. 6 is a cross-sectional view along A-A′ of FIGS. 5A and 5C according to one exemplary embodiment.

Except for positions of fifth and sixth contact holes CNT5 and CNT6, the light emitting diode display device 100 according to another exemplary embodiment of the present disclosure is substantially the same as the light emitting diode display device 100 according to one exemplary embodiment of the present disclosure shown in FIGS. 3A and 3B and FIGS. 4A and 4B.

According to the exemplary embodiment of the present disclosure shown in FIGS. 5A and 5B, a moat MOA can be provided to surround a portion of a light emitting diode LED. The moat MOA can include a first moat corresponding to a portion of moat MOA overlapped with a first connection electrode CE1 and a second moat corresponding to a portion of moat MOA overlapped with a second connection electrode CE2. The first moat and the second moat are spaced apart from each other and can be separated from each other. In this case, a second reflective plate REF2 provided in the portion of moat MOA overlapped with the first connection electrode CE1 can be spaced apart from a second reflective plate REF2 provided in the portion of moat MOA overlapped with the second connection electrode CE2, whereby they can be electrically separated from each other.

According to the exemplary embodiment of the present disclosure shown in FIGS. 5C and 5D, a moat MOA can be provided to surround all portions of a light emitting diode LED. The moat MOA can include a first moat corresponding to a portion of moat MOA overlapped with a first connection electrode CE1 and a second moat corresponding to a portion of moat MOA overlapped with a second connection electrode CE2. The first moat and the second moat can be connected to each other. The moat MOA can have a ring shape, and can have a circle shape in a plan view or a rectangular shape having angled or curved corners. In this case, a second reflective plate REF2 provided in the portion of moat MOA overlapped with the first connection electrode CE1 can be spaced apart from a second reflective plate REF2 provided in the portion of moat MOA overlapped with the second connection electrode CE2, whereby they can be electrically separated from each other. Referring to FIGS. 5A to 5D, a fifth contact hole CNT5 and a sixth contact hole CNT6 can be overlapped with the moat MOA. The fifth contact hole CNT5 and the sixth contact hole CNT6 can be provided in an inner portion of the moat MOA. That is, the moat MOA can include the fifth contact hole CNT5 and the sixth contact hole CNT6.

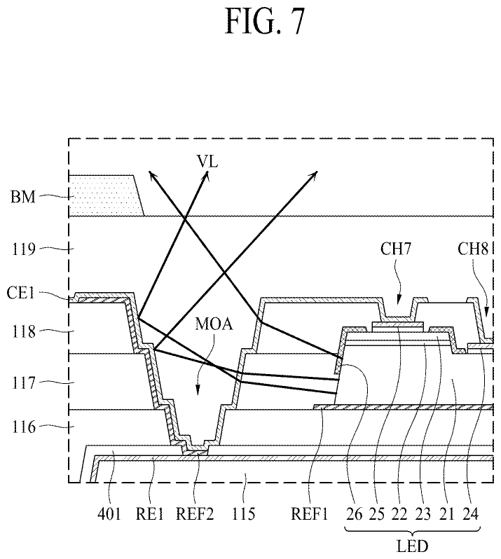

FIG. 7 illustrates an example of a light path in a light emitting diode display device according to exemplary embodiments of the present disclosure.

In case of a general light emitting diode display device, there is no moat MOA, a bank BM is provided in the periphery of a light emitting diode LED, and a plurality of contact holes adjacent to the light emitting diode LED are filled with the bank BM. In this case, light directed to a side surface of light emitted from the light emitting diode LED is absorbed by the bank BM so that a front luminance of the light emitting diode display device is lowered.

Referring to FIG. 7, according to exemplary embodiments of the present disclosure, a second planarization layer 117 has a first refractive index, a third planarization layer 118 has a second refractive index, and a fourth planarization layer 119 has a third refractive index. In order to refract lateral light VL of the light emitting diode LED to a front surface (viewing angle) 0°, the third refractive index can be greater than the first refractive index and the second refractive index. The first refractive index and the second refractive index can be the same as or different from each other, but the first refractive index and the second refractive index can be smaller than the third refractive index. As described above, one exemplary embodiment of the present disclosure can increase a front luminance by using the refractive index difference of the plurality of planarization layers 117, 118, and 119.

Some of the lateral light of the light emitting diode LED cannot be refracted to the front direction. According to exemplary embodiments of the present disclosure, the light emitting diode display device 100 can be provided in such a way that the light, which is not refracted to the front surface, faces to a sidewall located farther away from the light emitting diode LED among both sidewalls of the moat MOA while passing through the moat MOA. The light is reflected from a second reflective plate REF2 disposed over the sidewall of the moat MOA to the front surface (viewing angle of 0°) to increase the front luminance and light extraction efficiency.

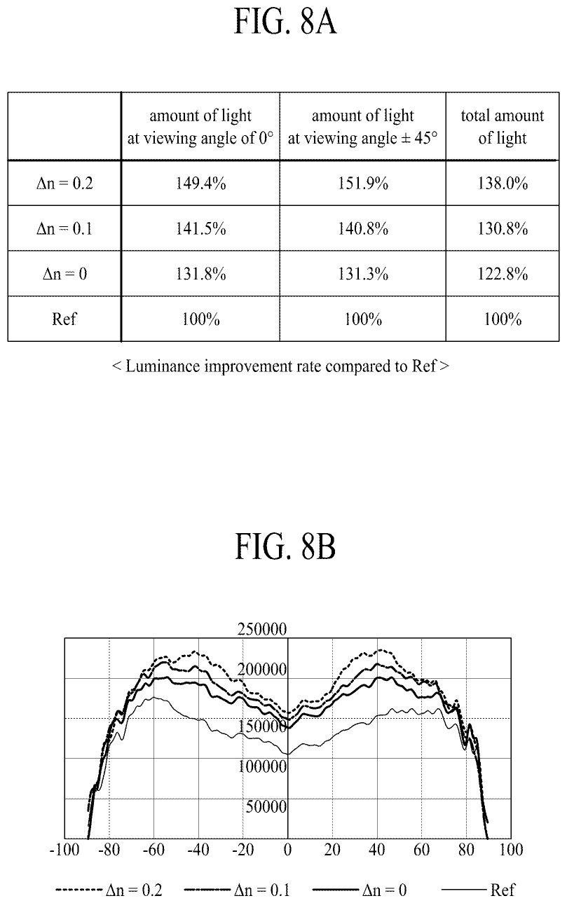

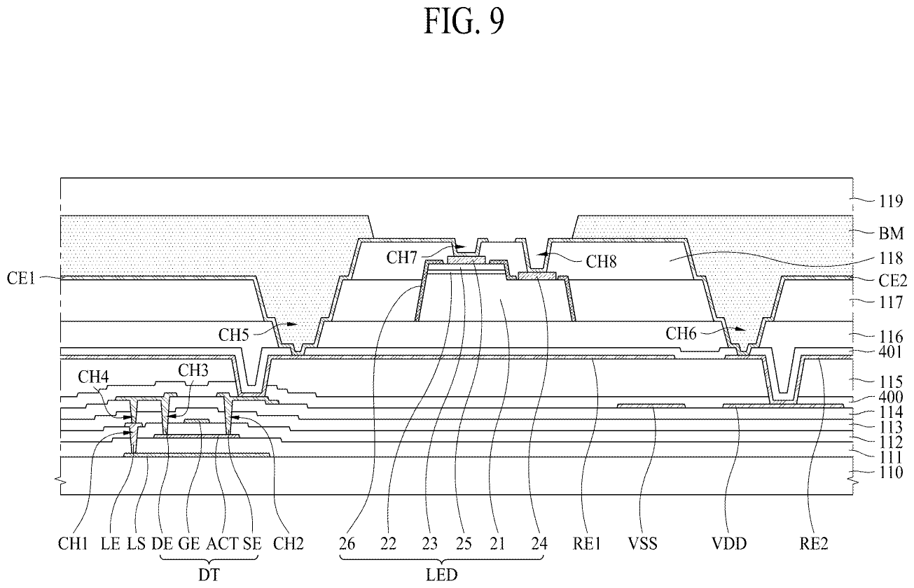

FIGS. 8A and 8B are diagrams illustrating simulation results for respective embodiments. FIG. 9 is a cross-sectional view of a light emitting diode display device in which a moat is not provided according to one embodiment.

In FIGS. 8A and 8B, ‘i) Ref.’ represents the amount of light for each viewing angle of the light emitting diode display according to FIG. 9, and ‘ii) Δn=0, Δn=0.1, Δn=0.2’ represents a case where the third refractive index is greater than or equal to the first refractive index. In this case, the first refractive index and the second refractive index are the same. Referring to FIGS. 8A and 8B, it can be seen that the total amount of light under the condition of ‘ii) Δn=0, Δn=0.1, Δn=0.2’ is increased by at least 22.8% as compared to the total amount of light under the condition of ‘i) Ref.’. In addition, under the condition of ‘ii) Δn=0, Δn=0.1, Δn=0.2’, it can be seen that the amount of light is increased by at least 31% in a condition of viewing angle ±45° as well as a condition of viewing angle of 0°.

In one exemplary embodiment of the present disclosure according to FIG. 9, a lower structure of the fourth insulating interlayer 401 is identical to that of the exemplary embodiment shown in FIG. 4A, whereby a description thereof will be omitted. According to one exemplary embodiment of the present disclosure according to FIG. 9, a first reflective plate REF1, a second reflective plate REF2, and a moat MOA are not provided.

A second planarization layer 117 and a third planarization layer 118 can be disposed over a plurality of light emitting diodes LED. The second planarization layer 117 and the third planarization layer 118 can be disposed to cover the plurality of light emitting diodes LED and are configured to fix and protect the plurality of light emitting diodes LED. After the third planarization layer 118 is deposited, a plurality of first connection electrodes CE1 and a plurality of second connection electrodes CE2 can be provided. The first connection electrode CE1 can be electrically connected with any one of a source electrode SE and a drain electrode DE of a driving transistor DT through a first reflective electrode RE1. The first connection electrode CE1 can be connected with a P-type electrode 25 of each of the plurality of light emitting diodes LED through a fifth contact hole CH5. The second connection electrode CE2 can be electrically connected with a first power line VDD through a second reflective electrode RE2. The second connection electrode CE2 can be connected with an N-type electrode 24 of each of the plurality of light emitting diodes LED through a contact hole provided in the third planarization layer 118. A bank BM can be provided over the first connection electrode CE1 and the second connection electrode CE2. The bank BM can be disposed over the third planarization layer 118 and can be configured to cover at least a portion of the first connection electrode CE1 and at least a portion of the second connection electrode CE2. The bank BM can be provided to fill the fifth contact hole CH5 over the first connection electrode CE1 provided in the fifth contact hole CH5. Also, the bank BM can be provided to fill the sixth contact hole CH6 over the second connection electrode CE2 provided in the sixth contact hole CH6.

The light emitting diode display device according to the present disclosure can include the moat in the portion adjacent to the light emitting diode and can have the reflective plate over the sidewall of the moat. In the light emitting diode display device according to the present disclosure, the light, which is not refracted to the front surface, in the light emitted from the side surface of the light emitting diode, is reflected on the reflective plate provided over the sidewall of the moat to the front surface so that it is possible to improve the front luminance and light extraction efficiency.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display device comprising:
a substrate;
a first layer over the substrate;
a light emitting element over the first layer;
a first planarization layer over the first layer, the first planarization layer configured to cover a side surface of the light emitting element and has a first refractive index;
a second planarization layer over the first planarization layer, the second planarization layer having a second refractive index; and
a bank over the second planarization layer,
wherein the first planarization layer includes a moat spaced apart from the light emitting element and surrounds at least a portion of the light emitting element.

2. The display device according to claim 1, wherein the second refractive index is greater than the first refractive index.

3. The display device according to claim 1, wherein the moat includes a first side surface and a second side surface located further away from the light emitting element than the first side surface, and the display device further comprising:
a first reflective plate over the second side surface of the moat.

4. The display device according to claim 3, further comprising:
a second reflective plate under the light emitting element.

5. The display device according to claim 1, wherein the first planarization layer includes organic material.

6. The display device according to claim 1, wherein the bank is non-overlapping with the moat.

7. The display device according to claim 1, wherein the light emitting element includes a light emitting diode including an N-type semiconductor layer, a light emitting layer, a P-type semiconductor layer, an N-type electrode, and a P-type electrode.

8. The display device according to claim 1, further comprising:
a driving transistor over the substrate;
a first connection electrode electrically connected with the driving transistor through a first contact hole; and
a second connection electrode electrically connected with a first power line through a second contact hole,
wherein the light emitting element is electrically connected with the driving transistor through the first connection electrode and is connected with the first power line through the second contact hole, and
the first contact hole and the second contact hole are overlapped with the moat.

9. The display device according to claim 8, wherein the first connection electrode is individually disposed for each of a plurality of subpixels, and the second connection electrode for each of the plurality of subpixels are connected to each other.

10. The display device according to claim 8, wherein the moat includes a first side surface and a second side surface located further away from the light emitting element than the first side surface, and the display device further comprising:
a first reflective plate over the second side surface of the moat.

11. The display device according to claim 10, wherein the first connection electrode and the second connection electrode are over the first reflective plate.

12. The display device according to claim 1, further comprising:
a driving transistor over the substrate;
a third planarization layer over the driving transistor;
a first reflective electrode and a second reflective electrode between the third planarization layer and the first layer;
a first connection electrode electrically connected with a first reflective electrode through a first contact hole; and
a second connection electrode electrically connected with a second reflective electrode through a second contact hole.

13. The display device according to claim 12, wherein the moat is spaced apart from the first contact hole and the second contact hole.

14. The display device according to claim 12, wherein the moat includes the first contact hole and the second contact hole.

15. A display device comprising:
a light emitting element over a substrate;
a first planarization layer over a side surface and an upper surface of the light emitting element, the first planarization layer having a first refractive index;
a moat over the first planarization layer and including a side surface facing the light emitting element; and
a first reflective plate over at least a portion of the side surface of the moat.

16. The display device according to claim 15, wherein the moat includes a first side surface and a second side surface facing each other,
wherein the second side surface includes an inclined surface in which a separation distance from the light emitting element gradually increases from a lower portion to an upper portion, and the first reflective plate is over at least a portion of the second side surface of the moat.

17. The display device according to claim 16, wherein the first reflective plate covers the second side surface of the moat and is over at least a portion of an upper surface of the first planarization layer.

18. The display device according to claim 16, wherein the first side surface includes an inclined surface in which a separation distance from the light emitting element gradually decreases from a lower portion to an upper portion, and the first reflective plate is not over the first side surface of the moat.

19. The display device according to claim 15, wherein the moat is spaced apart from the light emitting element.

20. The display device according to claim 15, wherein the moat surrounds at least a portion of the light emitting element.

21. The display device according to claim 15, further comprising:
a first connection electrode that electrically connects the light emitting element and a driving transistor; and
a second connection electrode that electrically connects the light emitting element and a power wiring,
wherein the first connection electrode and the second connection electrode are over the side surface of the moat.

22. The display device according to claim 21, wherein the first connection electrode and the second connection electrode are over the first reflective plate.

23. The display device according to claim 22, wherein the first reflective plate is under the first connection electrode is electrically separated from the first reflective plate that is under the second connection electrode.

24. The display device according to claim 21, wherein the moat includes a first moat at least partially overlapping the first connection electrode and a second moat at least partially overlapping the second connection electrode.

25. The display device according to claim 24, wherein the first moat and the second moat are spaced apart from each other.

26. The display device according to claim 24, wherein the first moat and the second moat are connected to each other.

27. The display device according to claim 24, wherein the first reflective plate that is in the first moat is spaced apart from the first reflective plate that is in the second moat.

28. The display device according to claim 21, further comprising:
a reflective electrode between the substrate and the light emitting element, the reflective electrode electrically connected with the driving transistor,
wherein the first connection electrode is electrically connected with the reflective electrode through a first contact hole.

29. The display device according to claim 21, further comprising:
a second reflective electrode between the substrate and the light emitting element, the second reflective electrode electrically connected with the power wiring,
wherein the second connection electrode is electrically connected with the second reflective electrode through a second contact hole.

30. The display device according to claim 28, wherein the first contact hole is spaced apart from the moat.

31. The display device according to claim 28, wherein the moat is between the first contact hole and the light emitting element.

32. The display device according to claim 28, wherein the moat is overlapped with the first contact hole.

33. The display device according to claim 28, wherein the moat exposes at least a portion of the upper surface of the reflective electrode on its lower surface, and the first reflective plate is in contact with the reflective electrode in the moat.

34. The display device according to claim 15, further comprising:
a second reflective plate under the light emitting element.

35. The display device according to claim 15, further comprising:
a second planarization layer over the first planarization layer, the second planarization layer having a second refractive index greater than the first refractive index.
